(19) United States
(12) Patent Application Publication
(10) Pub. No.: US 2020/0181454 A1
(43) Pub. Date: Jun. 11, 2020

(54) OXIDIZER FREE SLURRY FOR RUTHENIUM CMP

(71) Applicant: Cabot Microelectronics Corporation, Aurora, IL (US)

(72) Inventors: Cheng-Yuan KO, New Taipei (TW); Hung-Tsung HUANG, Tainan City (TW); Tyler J. CARTER, Naperville, IL (US)

(21) Appl. No.: 16/706,991

(22) Filed: Dec. 9, 2019

Related U.S. Application Data
(60) Provisional application No. 62/777,523, filed on Dec. 10, 2018.

(51) Int. Cl. C09G 1/02; H01L 21/321

(52) U.S. Cl. CPC C09G 1/02; H01L 21/3212

(57) ABSTRACT

The invention provides a chemical-mechanical polishing composition comprising(a) an abrasive having a Vickers hardness of 16 GPa or more, and (b) a liquid carrier, wherein the polishing composition is substantially free of an oxidizing agent and wherein the polishing composition has a pH of about 0 to about 7. The invention further provides a method of polishing a substrate, especially a substrate comprising ruthenium, with the polishing composition.

### BACKGROUND OF THE INVENTION

Compositions and methods for planarizing or polishing the surface of a substrate are well known in the art. Polishing compositions (also known as polishing slurries) typically contain an abrasive material in a liquid carrier and are applied to a surface by contacting the surface with a polishing pad saturated with the polishing composition. Typical abrasive materials include silicon dioxide, cerium oxide, aluminum oxide, zirconium oxide, and tin oxide. Polishing compositions are typically used in conjunction with polishing pads (e.g., a polishing cloth or disk). Instead of, or in addition to, being suspended in the polishing composition, the abrasive material may be incorporated into the polishing pad.

In the fabrication of microelectronic devices, ruthenium is emerging as a potential candidate for next generation liners and conducting metals due to low resistivity, good step coverage, and high thermal stability. To our knowledge, all existing platforms that provide high ruthenium removal rates utilize substrates formed from physical vapor deposition of ruthenium and polishing compositions comprising strong oxidizing agents and high abrasive particle loading. Unfortunately, these conventional approaches introduce safety concerns because certain oxidizing agents required to aid in removal of ruthenium can be toxic and/or explosive. In addition, certain species of oxidized ruthenium (e.g., RuO₄(g)) are toxic and volatile.

Moreover, current approaches for making ruthenium-based components have transitioned from physical vapor deposition to chemical vapor deposition and/or atomic layer deposition because these methods provide better conformity of ruthenium on the substrate surface.

Thus, there remains a need in the art for improved polishing compositions and methods for chemical-mechanical polishing of substrates comprising ruthenium that are oxidizer free to address safety concerns, yet strong enough to provide adequate ruthenium removal rates.

### BRIEF SUMMARY OF THE INVENTION

The invention provides a chemical-mechanical polishing composition comprising, consisting essentially of, or consisting of (a) an abrasive having a Vickers hardness of 16 GPa or more, and (b) a liquid carrier, wherein the polishing composition is substantially free of an oxidizing agent and wherein the polishing composition has a pH of about 0 to about 7.

The invention also provides a method of chemically-mechanically polishing a substrate comprising (i) providing a substrate, wherein the substrate comprises ruthenium on a surface of the substrate; (ii) providing a polishing pad; (iii) providing a chemical-mechanical polishing composition comprising: (a) an abrasive having a Vickers hardness of 16 GPa or more, and (b) a liquid carrier, wherein the polishing composition is substantially free of an oxidizing agent and wherein the polishing composition has a pH of about 0 to about 8 (iv) contacting the substrate with the polishing pad and the polishing composition; and (v) moving the polishing pad and the polishing composition relative to the substrate to abrade at least a portion of the ruthenium on the surface of the substrate to polish the substrate.

### DETAILED DESCRIPTION OF THE INVENTION

The invention provides a chemical-mechanical polishing composition comprising, consisting essentially of, or consisting of (a) an abrasive particle whose parent bulk materials has a Vickers hardness of 16 GPa or more, and (b) a liquid carrier, wherein the polishing composition is substantially free of an oxidizing agent and wherein the polishing composition has a pH of about 0 to about 8.

The chemical-mechanical polishing composition comprises an abrasive (e.g., abrasive particles), which desirably is suspended in the liquid carrier (e.g., water). The abrasive typically is in particulate form. The abrasive is formed from any suitable bulk material with a Vickers hardness of 16 GPa or more (e.g., about 30 GPa or more, about 40 GPa or more, about 50 GPa or more, about 60 GPa or more, or about 70 GPa or more, or about 80 GPa or more).

The Vickers hardness is a quantitative measurement that assesses a material's (i.e., the material that the abrasive is formed from) ability to resist deformation. For example, ceria has a Vickers hardness of about 4 GPa, zirconia has a Vickers hardness of about 6 GPa, silica (quartz) has a Vickers hardness of about 10 GPa, alumina has a Vickers hardness of about 16 to about 30 GPa, cubic boron nitride has a Vickers hardness of about 50, and diamond has an estimated Vickers hardness of about 80 (see, for example, Microstructure-Properly Correlations for Hard, Superhard, and Ultrahard Materials, Kanyanta, V., Ed., Springer, 2016; Dubrovinsky et al., Nature, 2001, 410(6829), 653; Din et al., Mater. Chem. Phys., 1998, 53(1), 48-54; and Maschio et al., J. Eur. Ceram. Soc., 1992, 9(2), 127-132.). The Vickers hardness can be measured by any suitable method, for example, a procedure such as ASTM standard C1327-15.

In some embodiments, the abrasive has a hardness of about 5 Mohs or more (e.g., about 5.5 Mohs or more, about 6 Mohs or more, about 6.5 Mohs or more, about 7 Mohs or more, about 7.5 Mohs or more, or about 8 Mohs or more). In some embodiments, the abrasive has a hardness of from about 5 Mohs to about 15 Mohs, for example, front about 5.5 Mohs to about 15 Mohs, from about 6 Mohs to about 15 Mohs, from about 6.5 Mohs to about 15 Mohs, from about 7 Mohs to about 15 Mohs, from about 7.5 Mohs to about 15 Mohs, or from about 8 Mohs to about 15 Mohs. In certain embodiments, the abrasive has a hardness of from about 8 Mohs to about 15 Mohs. The Mohs hardness is a qualitative measurement that assesses a material's (i.e., the material that the abrasive is formed from) relative ability to scratch another material.

In some embodiments, the abrasive comprises diamond, cubic boron nitride, alumina (Al₂O₃), silicon carbide (SiC), titania (TiO₂), tungsten carbide (WC), zirconia (ZrO₂), boron carbide (B₄C), tantalum carbide (TaC), titanium carbide (TiC) or combinations thereof. The diamond can be any suitable form of diamond. For example, term “diamond” includes particles (e.g., nanoparticles) of either natural or synthetic mono-crystalline diamond, poly-crystalline diamond, ultra-detonation diamond, or a combination thereof. As used herein, “cubic boron nitride” refers to the sphalerite structure of boron nitride, which has an analogous crystalline form to diamond. Any suitable alumina may be used, for example, alpha-alumina (α-Al₂O₃).

The abrasive can have any suitable particle size. As used herein, the particle size of an abrasive particle is the diameter of the smallest sphere that encompasses the particle. The abrasive particles can have an average (i.e., mean) particle size of about 1 nm or more, e.g., about 5 nm or more, about 10 nm or more, about 15 nm or more, about 20 nm or more, about 30 nm or more, about 40 nm or more, or about 50 nm or more. Alternatively, or in addition, the abrasive particles can have an average particle size of about 10 microns or less, e.g., about 1 micron or less, about 500 nm or less, about 400 nm or less, about 300 nm or less, about 200 nm or less, about 100 nm or less, or about 50 nm or less. Thus, the abrasive particles can have an average particle size within a range bounded by any two of the aforementioned endpoints. For example, the abrasive particles can have an average particle size of about 1 nm to about 10 microns, e.g., about 1 nm to about 1 micron, about 1 nm to about 500 nm, about 1 nm to about 250 nm, about 1 nm to about 200 nm, about 1 nm to about 100 nm, about 1 nm to about 50 nm, about 5 nm to about 1 micron, about 5 nm to about 500 nm, about 5 nm to about 250 nm, about 5 nm to about 200 nm, about 5 nm to about 100 nm, or about 5 nm to about 50 nm. In some embodiments, the abrasive particles have an average particle size of about 1 nm to about 1 micron. In certain embodiments, the abrasive particles have an average particle size of about 5 nm to about 500 nm.

The abrasive can be treated (e.g., cationic treated or anionic treated) or untreated. In some embodiments, the abrasive is treated (e.g., as described in U.S. Pat. No. 7,265,055). As used herein, an abrasive that is treated may be surface treated or doped with a corresponding cationic or anionic molecule or atom. Accordingly, the abrasive can have a zeta potential of about −100 mV or more at a pH of about 4, e.g., about −75 mV or more, about −50 mV or more, about −25 mV or more, or about 0 mV or more. Alternatively, or in addition, the abrasive can have a zeta potential at a pH of about 4 of about +100 mV or less, e.g., about +75 mV or less, about +50 mV or less, about +25 mV or less, or about 0 mV or less. Thus, the abrasive can have a zeta potential within a range bounded by any two of the aforementioned endpoints. For example, the abrasive can have a zeta potential at a pH of about 4 of about −100 mV to about +100 mV, e.g., about −75 mV to about +75 mV, about −50 mV to about +50 mV, about −100 mV about 0 mV, or about 0 mV to about +100 mV.

Any suitable amount of the abrasive can be present in the polishing composition. In some embodiments, the abrasive is present in the polishing composition at a concentration of about 0.0005 wt. % or more, e.g., about 0.001 wt. % or more, about 0.0025 wt. % or more, about 0.005 wt. % or more, about 0.01 wt. % or more, about 0.025 wt. % or more, or about 0.05 wt. % or more. More typically, the abrasive is present in the polishing composition at a concentration of about 0.001 wt. % or more, e.g., about 0.0025 wt. % or more, about 0.005 wt. % or more, about 0.01 wt. % or more, about 0.025 wt. % or more, or about 0.05 wt. % or more. Alternatively, or in addition, the abrasive is present in the polishing composition at a concentration of about 30 wt. % or less, e.g., about 20 wt. % or less, about 10 wt. % or less, about 5 wt. % or less, about 1 wt. % or less, about 0.5 wt. % or less, about 0.1 wt. % or less, or about 0.05 wt. % or less. More typically, the abrasive is present in the polishing composition at a concentration of about 1 wt. % or less, e.g., about 0.5 wt. % or less, about 0.1 wt. % or less, or about 0.05 wt. % or less. Thus, the abrasive can be present in the polishing composition within a range bounded by any two of the aforementioned endpoints. For example, the abrasive can be present in the polishing composition at a concentration of about 0.0005 wt. % to about 10 wt. %, e.g., about 0.001 wt. % to about 10 wt. %, about 0.001 wt. % to about 1 wt. %, about 0.001 wt. % to about 0.5 wt. %, about 0.001 wt. % to about 0.1 wt. %, about 0.001 wt. % to about 0.05 wt. %, about 0.005 wt. % to about 10 wt. %, about 0.005 wt. % to about 1 wt. %, about 0.005 wt. % to about 0.5 wt. %, about 0.005 wt. % to about 0.1 wt. %, about 0.005 wt. % to about 0.05 wt. %, about 0.01 wt. % to about 10 wt. %, about 0.01 wt. % to about 1 wt. %, about 0.01 wt. % to about 0.5 wt. %, about 0.01 wt. % to about 0.1 wt. %, about 0.01 wt. % to about 0.05 wt. %, about 0.05 wt. % to about 10 wt. %, about 0.05 wt. % to about 1 wt. %, about 0.05 wt. % to about 0.5 wt. %, about 0.05 wt. % to about 0.1 wt. %, or about 0.05 wt. % to about 0.05 wt. %. In certain embodiments, the abrasive is present in the polishing composition at a concentration of about 0.001 wt. % to about 1 wt. %.

The polishing composition described herein is substantially free of an oxidizing agent. As used herein, the phrase “substantially free of an oxidizing agent” refers to a composition comprising less than about 1 ppm of an oxidizing agent, e.g., less than about 100 ppb, less than about 10 ppb, less than about 1 ppb, less than about 100 ppt, less than about 10 ppt, or less than about 1 ppt. In certain embodiments, the polishing composition is free of an oxidizing agent (i.e., below the level of detection). As used herein, the phrase “oxidizing agent” refers to any chemical, other than ambient air, capable of oxidizing ruthenium above the +4 oxidation state. An exemplary list of such oxidizing agents includes, but is not limited to, peroxides (e.g., H₂O₂), periodic acid, oxone, bromates, bromites, hypobromites, chlorates, chlorites, hypochlorites, perchlorates, iodates, hypoiodates, periodates, cerium (IV) salts, permanganates, silver (III) salts, peroxyacetic acid, organo-halo-oxy compounds, monoperoxy sulfates, monoperoxy sulfites, monoperoxy thiosulfates, monoperoxyphosphates, monoperoxypyrophosphates, and monoperoxyhypophosphate

Generally, the chemical-mechanical polishing composition has a pH of about 8 or less, e.g., about 7 or less, e.g., about 6.5 or less, about 6 or less, about 5.5 or less, about 5 or less, about 4.5 or less, about 4 or less, about 3.5 or less, about 3 or less, about 2.5 or less, about 2 or less, about 1.5 or less, about 1 or less, or about 0.5 or less. Alternatively, or in addition, the chemical-mechanical polishing composition can have a pH of about 0 or more, e.g., about 0.5 or more, about 1 or more, about 1.5 or more, about 2 or more, about 2.5 or more, about 3 or more, about 3.5 or more, about 4 or more, or about 4.5 or more. Thus, the chemical-mechanical polishing composition can have a pH within a range bounded by any two of the aforementioned endpoints. For example, the polishing composition can have a pH of about 6 to about 7, about 5.5 to about 6.5, about 5 to about 6, about 4.5 to about 5.5, about 4 to about 5, about 3.5 to about 4.5, about 3 to about 4, about 2.5 to about 3.5, about 2 to about 3, about 1.5 to about 2.5, about 1 to about 2, about 0.5 to about 1.5, or about 0 to about 1. In some embodiments, the polishing composition has a pH of about 0 to about 7, for example, about 0 to about 6, about 0 to about 5, about 0 to about 4, about 0 to about 3, about 0 to about 2, about 1 to about 7, about 1 to about 6, about 1 to about 5, about 1 to about 4, about 1 to about 3, about 2 to about 7, about 2 to about 6, about 2 to about 5, about 2 to about 4, about 3 to about 7, about 3 to about 6, or about 3 to about 5. In certain embodiments, the polishing composition has a pH of about 2 to about 5, e.g., about 2, about 3, about 4, or about 5.

The chemical-mechanical polishing composition can comprise one or more compounds capable of adjusting (i.e., that adjust) the pH of the polishing composition (i.e., pH adjusting compounds). The pH of the polishing composition can be adjusted using any suitable compound capable of adjusting the pH of the polishing composition. The pH adjusting compound desirably is water-soluble and compatible with the other components of the polishing composition.

The compound capable of adjusting and buffering the pH can be selected from ammonium salts, alkali metal salts, carboxylic acids, alkali metal hydroxides, alkali metal carbonates, alkali metal bicarbonates, borates, organic acids (e.g., acetic acid), organic bases (e.g., amines), and combinations thereof. In certain embodiments, the pH is adjusted or buffered with an organic acid (e.g., acetic acid and/or potassium acetate). For example, the buffer can be an acidic chemical agent, a basic chemical agent, a neutral chemical agent, or a combination thereof. An exemplary list of buffers includes nitric acid, sulfuric acid, phosphoric acid, phthalic acid, citric acid, adipic acid, oxalic acid, malonic acid, maleic acid, acetic acid, ammonium hydroxide, phosphates, sulfates, acetates, malonates, oxalates, borates, ammonium salts, amines, polyols (e.g., trisbase), amino acids, and the like.

The polishing composition includes a liquid carrier. The liquid carrier contains water (e.g., deionized water) and optionally contains one or more water-miscible organic solvents. Examples of organic solvents that can be used include alcohols such as propenyl alcohol, isopropyl alcohol, ethanol, 1-propanol, methanol, 1-hexanol, and the like; aldehydes such as acetylaldehyde and the like; ketones such as acetone, diacetone alcohol, methyl ethyl ketone, and the like; esters such as ethyl formate, propyl formate, ethyl acetate, methyl acetate, methyl lactate, butyl lactate, ethyl lactate, and the like; ethers including sulfoxides such as dimethyl sulfoxide (DMSO), tetrahydrofuran, dioxane, diglyme, and the like; amides such as N, N-dimethylformamide, dimethylimidazolidinone, N-methylpyrrolidone, and the like; polyhydric alcohols and derivatives of the same such as ethylene glycol, glycerol, diethylene glycol, diethylene glycol monomethyl ether, and the like; and nitrogen-containing organic compounds such as acetonitrile, amylamine, isopropylamine, imidazole, dimethylamine, and the like. Preferably, the liquid carrier is water alone, i.e., without the presence of an organic solvent.

The polishing composition optionally further comprises one or more additives. Illustrative additives include buffers, dishing control agents, chelating agents, biocides, scale inhibitors, corrosion inhibitors, dispersants, etc. In some embodiments, the polishing composition further comprises a buffer, dishing control agent, chelating agent, biocide, corrosion inhibitor, dispersant, or a combination thereof. In certain embodiments, the polishing composition further comprises a buffer, a dishing control agent, and a biocide. In other embodiments, the polishing composition further comprises a buffer and a biocide.

In some embodiments, the chemical-mechanical polishing composition further comprises a dishing control agent. As used herein, the phrase “dishing control agent” refers to any chemical agent capable of reducing the loss of ruthenium within circuit traces, once the overlying blanket of ruthenium is removed, relative to a chemical mechanical polishing composition that does not contain the dishing control agent. Dishing and erosion can be determined using any suitable techniques. Examples of suitable techniques for determining dishing and erosion include scaiming electron microscopy, stylus profiling, and atomic force microscopy. Atomic force microscopy can be performed using the Dimension Atomic Force Profiler (AFP™) from Veeco (Plainview, N.Y.).

In some embodiments, the chemical-mechanical composition comprises a biocide. When present, the biocide can be any suitable biocide and can be present in the polishing composition in any suitable amount. An exemplary biocide is an isothiazolinone biocide. The polishing composition can comprise about 1 ppm to about 200 ppm biocide, e.g., about 10 ppm to about 200 ppm, about 10 ppm to about 150 ppm, about 20 ppm to about 150 ppm, about 50 ppm to about 150 ppm, about 1 ppm to about 150 ppm, or about 1 ppm to about 100 ppm.

The polishing composition can be produced by any suitable technique, many of which are known to those skilled in the art. The polishing composition can be prepared in a batch or continuous process. Generally, the polishing composition is prepared by combining the components of the polishing composition. The term “component” as used herein includes individual ingredients (e.g., abrasive, buffers, dishing control agents, chelating agents, biocides, scale inhibitors, corrosion inhibitors, dispersants, etc.) as well as any combination of ingredients (e.g., abrasive, buffers, dishing control agents, chelating agents, biocides, scale inhibitors, corrosion inhibitors, dispersants, etc.).

In some embodiments, the chemical-mechanical composition is stored in a single container. In other embodiments, the chemical-mechanical composition is stored in two or more containers, such that the chemical-mechanical composition is mixed at or near the point-of-use. In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use” if the components are combined about 5 minutes or less prior to being added in mixed form onto the platen, for example, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 minutes of the point-of-use, such as within 1 minute of the point-of-use.

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high-pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the abrasive and any optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component.

The invention also provides a method of polishing a substrate with the polishing composition described herein. The method of polishing a substrate comprises (i) providing a substrate; (ii) providing a polishing pad; (iii) providing the aforementioned chemical-mechanical polishing composition; (iv) contacting the substrate with the polishing pad and the chemical-mechanical polishing composition; and (v) moving the polishing pad and the chemical-mechanical polishing composition relative to the substrate to abrade at least a portion of a surface of the substrate to polish the substrate.

In particular, the invention further provides a method of chemically-mechanically polishing a substrate comprising: (i) providing a substrate, wherein the substrate comprises ruthenium on a surface of the substrate; (ii) providing a polishing pad; (iii) providing a chemical-mechanical polishing composition comprising: (a) an abrasive having a Vickers hardness of 20 GPa or more, and (b) a liquid carrier, wherein the polishing composition is substantially free of an oxidizing agent and wherein the polishing composition has a pH of about 0 to about 7; (iv) contacting the substrate with the polishing pad and the polishing composition; and (v) moving the polishing pad and the polishing composition relative to the substrate to abrade at least a portion of the ruthenium on the surface of the substrate to polish the substrate.

The chemical-mechanical polishing composition can be used to polish any suitable substrate and is especially useful for polishing substrates comprising at least one layer (typically a surface layer) comprised of a dielectric material, for example a low-K dielectric material. Suitable substrates include wafers used in the semiconductor industry. The wafers typically comprise or consist of, for example, a metal, metal oxide, metal nitride, metal carbide, metal composite, metal alloy, a low dielectric material, or combinations thereof. The method of the invention is particularly useful for polishing substrates comprising ruthenium.

In preferred embodiments, the substrate comprises ruthenium (e.g., Ru⁰). The ruthenium can be applied to the substrate surface by any suitable method. For example, the ruthenium can be applied to the substrate surface using physical vapor deposition (“PVD”), chemical vapor deposition (“CVD”), atomic layer deposition (“ALD”), electrochemical plating (“ECP”) or any combination thereof. In certain embodiments, the ruthenium is applied to the surface of the substrate with CVD, ECP and/or ALD.

In embodiments where the ruthenium further comprises oxygen, the ruthenium can be any suitable ruthenium species in any suitable oxidation state. For example, the ruthenium can be Ru(OH)₂⁺, Ru³⁺, Ru(OH)₃.H₂O, RuO₂.2H₂O, Ru₂O, H₂RuO₅, Ru₄(OH)₁₂⁴⁺, Ru(OH)₂²⁺, or a combination thereof. In certain embodiments, the substrate comprises Ru⁰, Ru(OH)₂⁺, Ru³⁺, Ru(OH)₃.H₂O, RuO₂.2H₂O, Ru₄(OH)₁₂²⁺, Ru(OH)₂²⁺, or a combination thereof.

The chemical-mechanical polishing composition of the invention desirably exhibits a high removal rate when polishing a substrate comprising ruthenium according to a method of the invention. For example, when polishing silicon wafers comprising ruthenium in accordance with an embodiment of the invention, the polishing composition desirably exhibits a ruthenium removal rate of about 100 Å/min or higher, e.g., 150 Å/min or higher, about 200 Å/min or higher, about 250 Å/min or higher, about 300 Å/min or higher, about 350 Å/min or higher, about 400 Å/min or higher, about 450 Å/min or higher, or about 500 Å/min or higher.

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof. Soft polyurethane polishing pads are particularly useful in conjunction with the inventive polishing method. Typical pads include but are not limited to SURFIN™ 000, SURFIN™ SSW1, SPM3100 (commercially available from, for example, Eminess Technologies), POLITEX™, and Fujibo POLYPAS™ 27. Particularly preferred polishing pads are the EPIC™ D100 pad and NEXPLANAR™ E6088 pad commercially available from Cabot Microelectronics and the IC1010™ pad commercially available from Dow Chemical Company.

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. No. 5,196,353, U.S. Pat. No. 5,433,651, U.S. Pat. No. 5,609,511, U.S. Pat. No. 5,643,046, U.S. Pat. No. 5,658,183, U.S. Pat. No. 5,730,642, U.S. Pat. No. 5,838,447, U.S. Pat. No. 5,872,633, U.S. Pat. No. 5,893,796, U.S. Pat. No. 5,949,927, and U.S. Pat. No. 5,964,643. Desirably, the inspection or monitoring of the progress of the polishing process with respect to a substrate being polished enables the determination of the polishing end-point, i.e., the determination of when to terminate the polishing process with respect to a particular substrate.

The invention is further illustrated by the following embodiments.

### Embodiments

(1) In embodiment (1) is provided a chemical-mechanical polishing composition comprising: (a) an abrasive having a Vickers hardness of 16 GPa or more, and (b) a liquid carrier, wherein the polishing composition is substantially free of an oxidizing agent and wherein the polishing composition has a pH of about 0 to about 8.

(2) In embodiment (2) is provided the polishing composition of embodiment (1), wherein the polishing composition has a pH of about 1 to about 6.

(3) In embodiment (3) is provided the polishing composition of embodiment (2), wherein the polishing composition has a pH of about 2 to about 5.

(4) In embodiment (4) is provided the polishing composition of any one of embodiments (1)-(3), wherein the abrasive has a Vickers hardness of 40 GPa or more.

(5) In embodiment (5) is provided the polishing composition of embodiment (4), wherein the abrasive has a Vickers hardness of 50 GPa or more.

(6) In embodiment (6) is provided the polishing composition of any one of embodiments (1)-(5), wherein the abrasive comprises diamond, cubic boron nitride, α-Al₂O₃, or a combination thereof.

(7) In embodiment (7) is provided the polishing composition of embodiment (6), wherein the abrasive comprises diamond.

(8) In embodiment (8) is provided the polishing composition of any one of embodiments (1)-(7), wherein the abrasive is present in the polishing composition at a concentration of about 0.001 wt. % to about 1 wt. %.

(9) In embodiment (9) is provided the polishing composition of embodiment (8), wherein the abrasive is present in the polishing composition at a concentration of about 0.001 wt. % to about 0.1 wt. %.

(10) In embodiment (10) is provided the polishing composition of embodiment (9), wherein the abrasive is present in the polishing composition at a concentration of about 0.001 wt. % to about 0.05 wt. %.

(11) In embodiment (11) is provided the polishing composition of any one of embodiments (1)-(10), wherein the abrasive has an average particle size of about 1 nm to about 1 micron.

(12) In embodiment (12) is provided the polishing composition of embodiment (11), wherein the abrasive has an average particle size of about 5 nm to about 500 nm.

(13) In embodiment (13) is provided the polishing composition of embodiment (12), wherein the abrasive has an average particle size of about 5 nm to about 200 nm.

(14) In embodiment (14) is provided the polishing composition of any one of embodiments (1)-(13), wherein the polishing composition further comprises a buffer, dishing control agent, chelating agent, biocide, corrosion inhibitor, dispersant, or a combination thereof.

(15) In embodiment (15) is provided the polishing composition of any one of embodiments (1)-(14), wherein the polishing composition further comprises a buffer, a dishing control agent, and a biocide.

(16) In embodiment (16) is provided the polishing composition of any one of embodiments (1)-(14), wherein the polishing composition further comprises a buffer and a biocide.

(17) In embodiment (17) is provided a method of chemically-mechanically polishing a substrate comprising: (i) providing a substrate, wherein the substrate comprises ruthenium on a surface of the substrate; (ii) providing a polishing pad; (iii) providing a chemical-mechanical polishing composition comprising: (a) an abrasive having a Vickers hardness of 20 GPa or more, and (b) a liquid carrier, wherein the polishing composition is substantially free of an oxidizing agent and wherein the polishing composition has a pH of about 0 to about 7; (iv) contacting the substrate with the polishing pad and the polishing composition; and (v) moving the polishing pad and the polishing composition relative to the substrate to abrade at least a portion of the ruthenium on the surface of the substrate to polish the substrate.

(18) In embodiment (18) is provided the method of embodiment (17), wherein the ruthenium is applied to the surface of the substrate with chemical vapor deposition.

(19) In embodiment (19) is provided the method of embodiment (17), wherein the ruthenium is applied to the surface of the substrate with atomic layer deposition.

(20) In embodiment (20) is provided the method of any one of embodiments (17)-(19), wherein the ruthenium further comprises carbon, oxygen, nitrogen, or a combination thereof.

(21) In embodiment (21) is provided the method of any one of embodiments (17)-(20), wherein the polishing composition has a pH of about 1 to about 6.

(22) In embodiment (22) is provided the method of embodiment (21), wherein the polishing composition has a pH of about 2 to about 5.

(23) In embodiment (23) is provided the method of any one of embodiments (17)-(22), wherein the abrasive has a Vickers hardness of 40 GPa or more.

(24) In embodiment (24) is provided the method of embodiment (23), wherein the abrasive has a Vickers hardness of 50 GPa or more.

(25) In embodiment (25) is provided the method of any one of embodiments (17)-(24), wherein the abrasive comprises diamond, cubic boron nitride, α-Al₂O₃, or a combination thereof.

(26) In embodiment (26) is provided the method of embodiment (25), wherein the abrasive comprises diamond.

(27) In embodiment (27) is provided the method of any one of embodiments (17)-(26), wherein the abrasive is present in the polishing composition at a concentration of about 0.001 wt. % to about 1 wt. %.

(28) In embodiment (28) is provided the method of embodiment (27), wherein the abrasive is present in the polishing composition at a concentration of about 0.001 wt. % to about 0.1 wt. %.

(29) In embodiment (29) is provided the method of embodiment (28), wherein the abrasive is present in the polishing composition at a concentration of about 0.001 wt. % to about 0.05 wt. %.

(30) In embodiment (30) is provided the method of any one of embodiments (17)-(29), wherein the abrasive has an average particle size of about 1 nm to about 1 micron.

(31) In embodiment (31) is provided the method of embodiment (30), wherein the abrasive has an average particle size of about 5 nm to about 500 nm.

(32) In embodiment (32) is provided the method of embodiment (31), wherein the abrasive has an average particle size of about 5 nm to about 200 nm.

(33) In embodiment (33) is provided the method of any one of embodiments (17)-(32), wherein the polishing composition further comprises a buffer, dishing control agent, chelating agent, biocide, corrosion inhibitor, dispersant, or a combination thereof.

(34) In embodiment (34) is provided the method of any one of embodiments (17)-(33), wherein the polishing composition further comprises a buffer, a dishing control agent, and a biocide.

(35) In embodiment (35) is provided the method of any one of embodiments (17)-(33), wherein the polishing composition further comprises a buffer and a biocide.

These following examples further illustrate the invention but, of course, should not be construed as in any way limiting its scope.

### EXAMPLES

The following abbreviations are used throughout the Examples: removal rate (RR); physical vapor deposition (PVD); chemical vapor deposition (CVD); atomic laser deposition (ALD); ruthenium (Ru); nano-diamond (ND); cubic boron nitride (cBN); α-Al₂O₃ (AA); potassium acetate (AcOK); and tetraethyl orthosilicate (TEOS).

The following examples further illustrate the invention but, of course, should not be construed as in any way limiting its scope.

### Example 1

This example demonstrates the effect of ruthenium deposition method on the removal rate of ruthenium as exhibited by a comparative polishing slurry comprising a surface-coated alumina and hydrogen peroxide.

Separate substrates (i.e., 2×2 inch coupon wafers) comprising ruthenium coating deposited with PVD (“Substrate 1A”) and CVD (“Substrate 1B”) were polished with a composition comprising 1 wt. % hydrogen peroxide and Al₂O₃ particles surface-coated with a 2-acrylamido-2-methyl-1-propanesulfonic acid (AMPS) homopolymer at a pH of 8.4. The substrates were polished on a Logitech 2 benchtop polishing machine at 1.5 PSI (10.3 kPa) downforce using a Fujibo pad conditioned with a product commercially identified as A82 (3M, St. Paul, Minn.). Logitech polishing parameters were as follows: headspeed=93 rpm, platen speed=87 rpm, total flow rate=150 mL/min. Removal rates were calculated by measuring the film thickness, using spectroscopic elipsometry, and subtracting the final thickness from the initial thickness. Following polishing, the ruthenium removal rates were determined, and the results are set forth in Table 1.

TABLE 1
Ruthenium Removal Rate as a Function
of Ruthenium Deposition Method

| | Ruthenium | Ruthenium Removal Rate |
|---|---|---|
| Substrate | Deposition Method | (Å/min) |
| 1A | Physical Vapor Deposition | 300 |
| 1B | Chemical Vapor Deposition | 23 |

As is apparent from the results set forth in Table 1, the ruthenium removal rate of Substrate 1A, prepared from PVD, is more efficient than the ruthenium removal rate of Substrate 1B, prepared from CVD. These results show that a polishing composition comprising an abrasive and an oxidizing agent may provide adequate ruthenium removal for substrates prepared by PVD, but provide inadequate ruthenium removal for substrates prepared by CVD.

### Example 2

This example demonstrates the effect of oxidizing agent, abrasive, and pH on the ruthenium removal rate for a substrate comprising ruthenium deposited by CVD.

Separate substrates (i.e., 2×2 inch coupon wafers) comprising ruthenium coating deposited with CVD were polished with twelve (12) different polishing compositions, i.e., Polishing Compositions 2A-2L (Table 2). Each polishing composition contained an abrasive, oxidizing agent, and additive of the type and in the amounts described in Table 2, and each polishing composition had a pH as stated in Table 2. The substrates were polished on a Logitech 2 benchtop polishing machine at 1.5 PSI (10.3 kPa) downforce using a Fujibo pad conditioned with a product commercially identified as A82 (3M, St. Paul, Minn.). Logitech polishing parameters were as follows: headspeed=93 rpm, platen speed=87 rpm, total flow rate=150 mL/min. Removal rates were calculated by measuring the film thickness, using spectroscopic elipsometry, and subtracting the final thickness from the initial thickness. Following polishing, the ruthenium removal rates were determined, and the results are set forth in Table 2.

TABLE 2
Ruthenium Removal Rate as a Function of Oxidizing Agent, Abrasive, and pH

| | | | | | Ruthenium |
|---|---|---|---|---|---|
| Polishing | | Oxidizing | | | Removal Rate |
| Composition | Abrasive | Agent(s) | Additive(s) | pH | (Å/min) |
| 2A (Comparative) | 100 ppm ND¹ | None | 100 ppm | 10 | 12 |
| | | | AcOK | | |
| 2B (Comparative) | 100 ppm ND¹ | Fe(NO₃)₃ | 100 ppm | 4 | 26 |
| | | | AcOK | | |
| 2C (Comparative) | 100 ppm ND¹ | Fe(NO₃)₃ (with | 100 ppm | 4 | 47 |
| | | malonic acid | AcOK | | |
| | | stabilizer) | | | |
| 2D (Comparative) | 2 wt. % Surface- | None | 1 wt. % | 8.4 | 0 |
| | Coated² Al₂O₃ | | NH₄OH | | |
| 2E (Comparative) | 100 ppm ND¹ | 1 wt. % H₂O₂ | 100 ppm | 10 | 13 |
| | | | AcOK | | |
| 2F (Comparative) | 100 ppm ND¹ | 1 wt. % H₂O₂ | 100 ppm | 7 | 30 |
| | | | AcOK | | |
| 2G (Comparative) | 100 ppm ND¹ | 1 wt. % H₂O₂ | 100 ppm | 4 | 66 |
| | | | AcOK | | |
| 2H (Comparative) | 100 ppm ND¹ | 1 wt. % H₂O₂/ | 100 ppm | 4 | 17 |
| | | Fe(NO₃)₃ | AcOK | | |
| 2I (Comparative) | 100 ppm ND¹ | 1 wt. % H₂O₂/ | 100 ppm | 4 | 47 |
| | | Fe(NO₃)₃ (with | AcOK | | |
| | | malonic acid | | | |
| | | stabilizer) | | | |
| 2J (Comparative) | 2 wt. % Surface- | 1 wt. % H₂O₂ | 1 wt. % | 8.4 | 96 |
| | Coated² Al₂O₃ | | NH₄OH | | |
| 2K (Inventive) | 100 ppm ND¹ | None | 100 ppm | 7 | 85 |
| | | | AcOK | | |
| 2L (Inventive) | 100 ppm ND¹ | None | 100 ppm | 4 | 233 |
| | | | AcOK | | |

¹refers to anionic treated nano-diamond particles with a charge of about −35 mV and a particle size of about 75 nm (commercially available from Engis ® Corporation; Wheeling, Illinois)
²refers to an abrasive particle that has been surface-coated with a 2-acrylamido-2-methyl-1-propanesulfonic acid (AA-AMPS) homopolymer

As is apparent from the results set forth in Table 2, Inventive Polishing Compositions 2K and 2L, which contained no oxidizing agent at a pH of 7 and 4, respectively, exhibited a higher ruthenium removal rate than Comparative Polishing Compositions 2A-2C and 2E-2H, which contained an oxidizing agent at a pH of 4, 7, or 10, or no oxidizing agent at a pH of 10.

Inventive Polishing Compositions 2K and 2L, comprising diamond as the abrasive and no oxidizing agent, outperformed Comparative Polishing Compositions 2F and 2G, comprising diamond as the abrasive and an oxidizing agent, at similar pH values. In addition, Comparative Polishing Composition 2A and Inventive Polishing Compositions 2K and 2L, having pH values of 10, 7, and 4, respectively, demonstrate that as the pH decreases, removal rate increases for polishing compositions comprising a hard abrasive, such as diamond, and no oxidizing agent. These results show that polishing compositions containing a hard abrasive such as diamond, no oxidizing agent, and a pH of 7 or less are more efficient at ruthenium removal than polishing compositions containing a hard abrasive such as diamond, an oxidizing agent, and/or a pH of greater than 7 when the ruthenium coating is deposited with CVD.

### Example 3

This example demonstrates the effect of abrasive on the ruthenium removal rate for a substrate comprising ruthenium deposited by CVD.

Separate substrates (i.e., 2×2 inch coupon wafers) comprising ruthenium coating deposited with CVD were polished with nine (9) different polishing compositions, i.e., Polishing Compositions 3A-3I (Table 3). Each polishing composition contained an abrasive as described in Table 3, as well as 100 ppm AcOK, and each had a pH of 4. None of the polishing compositions contained an oxidizing agent. The substrates were polished on a Logitech 2 benchtop polishing machine at 1.5 PSI (10.3 kPa) downforce using an M2000® pad (Cabot Microelectronics Corporation, Aurora, Ill.), and conditioned with a A165 conditioner (3M, St. Paul, Minn.). Logitech polishing parameters were as follows: headspeed=93 rpm, platen speed=87 rpm, total flow rate=100 mL/min. Removal rates were calculated by measuring the film thickness, using spectroscopic elipsometry, and subtracting the final thickness from the initial thickness. Following polishing, the ruthenium removal rates were determined, and the results are set forth in Table 3.

TABLE 3
Ruthenium Removal Rate as a Function of Abrasive

| | | Ruthenium |
|---|---|---|
| | | Removal |
| Polishing | | Rate |
| Composition | Abrasive | (Å/min) |
| 3A (Comparative) | 1 wt. % Treated cationic colloidal silica | 51 |
| 3B (Comparative) | 1 wt. % Surface-Coated³ CeO₂ | 36 |
| 3C (Comparative) | 1 wt. % Treated³ α-Al₂O₃ | 12 |
| 3D (Comparative) | 1 wt. % Treated³ α-Al₂O₃ | 36 |
| 3E (Comparative) | 1 wt. % Treated³ ZrO₄ | 15 |
| 3F (Inventive) | 1 wt. % α-Al₂O₃ | 324 |
| | (mean particle size about 130 nm) | |
| 3G (Inventive) | 1 wt. % α-Al₂O₃ | 168 |
| | (mean particle size about 60 nm) | |
| 3H (Inventive) | 100 ppm cBN | 459 |
| 3I (Inventive) | 100 ppm ND⁴ | 573 |

³refers to an abrasive particle that has been surface-coated with an acrylic acid-2-acrylamido-2-methyl-1-propanesulfonic acid (AA-AMPS) copolymer
⁴refers to MDP Hydrogen D treated nano-diamond particles with a charge of about +30 mV and a particle size of about 55 nm (commercially available from Engis ® Corporation; Wheeling, Illinois)

As is apparent from the results set forth in Table 3, Comparative Polishing Compositions 3B-3E, which contained surface-coated abrasives, exhibited low ruthenium removal rates when the ruthenium coating was deposited with CVD. These results show that surface-coated abrasives are not sufficient abrasives for ruthenium removal in the absence of an oxidizing agent when the ruthenium coating is deposited with CVD.

In addition, the results set forth in Table 3 show that Inventive Polishing Compositions 3F-3I, which contained α-Al₂O₃, cBN, or ND, exhibited higher ruthenium removal rates than Comparative Polishing Compositions 3A-3E, which are softer abrasives with a Vickers hardness of less than 20 GPa. Table 3 also shows that Inventive Polishing Compositions containing the hardest abrasives, i.e., cBN and ND (see Polishing Compositions 3H and 3I), were the most efficient at ruthenium removal. These results show that polishing compositions containing a hard abrasive such as α-Al₂O₃, cBN, or ND are more efficient at ruthenium removal than polishing compositions containing a surface-coated abrasive when the ruthenium coating is deposited with CVD.

### Example 4

This example demonstrates the effect of abrasive and pH on the ruthenium removal rate for a substrate comprising ruthenium deposited by CVD.

Separate substrates (i.e., 2×2 inch coupon wafers) comprising ruthenium coating deposited with CVD were polished with six (6) different polishing compositions, i.e., Polishing Compositions 4A-4F (Table 4). Each polishing composition contained an abrasive of the type and in the amount described in Table 4, and each polishing composition had the pH stated in Table 4. Each polishing composition also contained 100 ppm AcOK as an additive, except for Comparative Polishing Composition 4A, which did not contain any AcOK or other additive. None of the polishing compositions contained an oxidizing agent. The substrates were polished on a Logitech 2 benchtop polishing machine at 1.5 PSI (10.3 kPa) downforce using an M2000® pad conditioned with a A165 conditioner. Logitech polishing parameters were as follows: headspeed=93 rpm, platen speed=87 rpm, total flow rate=100 mL/min. Removal rates were calculated by measuring the film thickness, using spectroscopic elipsometry, and subtracting the final thickness from the initial thickness. Following polishing, the ruthenium removal rates were determined, and the results are set forth in Table 4.

TABLE 4
Ruthenium Removal Rate as a Function of Abrasive and pH

| | | | Ruthenium |
|---|---|---|---|
| | | | Removal |
| Polishing | | | Rate |
| Composition | Abrasive | pH | (Å/min) |
| 4A (Comparative) | 1 wt. % Treated⁵ α- | 4 | 43 |
| | Al₂O₃ | | |
| 4B (Inventive) | 50 ppm ND⁶ | 4 | 72 |
| 4C (Inventive) | 100 ppm ND⁶ | 3.5 | 203 |
| 4D (Inventive) | 100 ppm ND⁶ | 4 | 193 |
| 4E (Inventive) | 100 ppm ND⁶ | 4.5 | 190 |
| 4F (Inventive) | 300 ppm ND⁶ | 4 | 509 |

⁵refers to an abrasive particle that has been surface-coated with a 2-acrylamido-2-methyl-1-propanesulfonic acid (AMPS) homopolymer
⁶refers to anionic treated nano-diamond particles with a charge of about −35 mV and a particle size of about 75 nm (commercially available from Engis ® Corporation; Wheeling, Illinois)

As is apparent from the results set forth in Table 4, Inventive Polishing Compositions 4B-4F, which contained ND as the abrasive, exhibited higher ruthenium removal rates than Comparative Polishing Composition 4A, which contained surface-coated α-alumina. These results show that polishing compositions containing a hard abrasive such as diamond provide more efficient ruthenium removal than polishing compositions comprising a surface-coated α-Al₂O₃ abrasive when the ruthenium coating is deposited with CVD.

In addition, the results set forth in Table 4 show that as the pH of the polishing composition decreases, the ruthenium removal rate increases (see, for example, Polishing Compositions 4C-4E) and when the concentration of the abrasive increases, the ruthenium removal rate increases (see, for example Polishing Compositions 4A, 4C, and 4F).

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) an abrasive having a Vickers hardness of 16 GPa or more, and
(b) a liquid carrier,
wherein the polishing composition is substantially free of an oxidizing agent and wherein the polishing composition has a pH of about 0 to about 8.

2. The polishing composition of claim 1, wherein the polishing composition has a pH of about 1 to about 6.

3. The polishing composition of claim 2, wherein the polishing composition has a pH of about 2 to about 5.

4. The polishing composition of claim 1, wherein the abrasive has a Vickers hardness of 40 GPa or more.

5. The polishing composition of claim 4, wherein the abrasive has a Vickers hardness of 50 GPa or more.

6. The polishing composition of claim 1, wherein the abrasive comprises diamond, cubic boron nitride, α-Al₂O₃, or a combination thereof.

7. The polishing composition of claim 6, wherein the abrasive comprises diamond.

8. The polishing composition of claim 1, wherein the abrasive is present in the polishing composition at a concentration of about 0.001 wt. % to about 1 wt. %.

9. The polishing composition of claim 8, wherein the abrasive is present in the polishing composition at a concentration of about 0.001 wt. % to about 0.1 wt. %.

10. The polishing composition of claim 9, wherein the abrasive is present in the polishing composition at a concentration of about 0.001 wt. % to about 0.05 wt. %.

11. The polishing composition of claim 1, wherein the abrasive has an average particle size of about 1 nm to about 1 micron.

12. The polishing composition of claim 11, wherein the abrasive has an average particle size of about 5 nm to about 500 nm.

13. The polishing composition of claim 12, wherein the abrasive has an average particle size of about 5 nm to about 200 nm.

14. A method of chemically-mechanically polishing a substrate comprising:
(i) providing a substrate, wherein the substrate comprises ruthenium on a surface of the substrate;
(ii) providing a polishing pad;
(iii) providing a chemical-mechanical polishing composition comprising:
(a) an abrasive having a Vickers hardness of 16 GPa or more, and
(b) a liquid carrier,
wherein the polishing composition is substantially free of an oxidizing agent and
wherein the polishing composition has a pH of about 0 to about 7;
(iv) contacting the substrate with the polishing pad and the polishing composition; and
(v) moving the polishing pad and the polishing composition relative to the substrate to abrade at least a portion of the ruthenium on the surface of the substrate to polish the substrate.

15. The method of claim 14, wherein the ruthenium further comprises carbon, oxygen, nitrogen, or a combination thereof.

16. The method of claim 14, wherein the polishing composition has a pH of about 1 to about 6.

17. The method of claim 14, wherein the abrasive comprises diamond, cubic boron nitride, α-Al₂O₃, or a combination thereof.

18. The method of claim 17, wherein the abrasive comprises diamond.

19. The method of claim 14, wherein the abrasive is present in the polishing composition at a concentration of about 0.001 wt. % to about 1 wt. %.

20. The method of claim 14, wherein the abrasive has an average particle size of about 1 nm to about 1 micron.
